(19) United States
(12) Patent Application Publication
(10) Pub. No.: US 2025/0241103 A1
(43) Pub. Date: Jul. 24, 2025

(54) DISPLAY PANEL, DISPLAY MODULE AND DISPLAY SYSTEM

(71) Applicants: BOE MLED Technology Co., Ltd., Beijing (CN); BOE Technology Group Co., Ltd., Beijing (CN)

(72) Inventors: Ruoyu MA, Beijing (CN); Xiurong WANG, Beijing (CN)

(73) Assignees: BOE MLED Technology Co., Ltd., Beijing (CN); BOE Technology Group Co., Ltd., Beijing (CN)

(21) Appl. No.: 18/703,372

(22) PCT Filed: Aug. 4, 2023
(86) PCT No.: PCT/CN2023/111330

§ 371 Date: Apr. 22, 2024

(51) Int. Cl. H10H 29/49; H10H 29/24

(52) U.S. Cl. CPC H10H 29/49; H10H 29/24

(57) ABSTRACT

Provided is a display panel, including: a backplane, and a plurality of light-emitting units. The light-emitting unit includes a driving portion and a plurality of light-emitting portions fixed on the backplane. The backplane is integrated with a plurality of sets of first signal lines and a plurality of sets of second signal lines. A set of the first signal lines is electrically connected to each of the light-emitting units arranged along a first direction. A set of the second signal lines is electrically connected to each of the light-emitting units arranged along a second direction. The first direction is different from the second direction. A functional portion is provided in a region enclosed by at least part of adjacent first signal lines and at least at least part of adjacent second signal lines. The functional portion is a through hole penetrating through the backplane.

### CROSS-REFERENCE TO RELATED APPLICATION

The application is a U.S. national stage of international application No. PCT/CN2023/111330, filed on Aug. 4, 2023, the content of which is herein incorporated by reference in its entirety.

### TECHNICAL FIELD

The present disclosure relates to the field of display technologies, and in particular, relates to a display panel, a display module and a display system.

### BACKGROUND

With the development of the display technologies, mini light-emitting diode (LED) display panels will become a new generation of display media with the most advantages and have been widely because of their advantages of pure chromaticity, wide dynamic range, high brightness, high definition, low operating voltage, low power consumption, long service life, impact resistance, large viewing angle, stable and reliable operation, and the like.

However, the current LED display panels generally only have a display function, resulting in a single function of the LED display panels.

### SUMMARY

Embodiments of the present disclosure provide a display panel, a display module and a display system. The technical solutions are as follows.

According to some embodiments of the present disclosure, a display panel is provided. The display panel includes:
a backplane; and
a plurality of light-emitting units arranged in an array on a side of the backplane, wherein the light-emitting unit includes a driving portion and a plurality of light-emitting portions that are fixed on the backplane;
wherein the backplane is integrated with a plurality of sets of first signal lines and a plurality of sets of second signal lines, wherein a set of the first signal lines is electrically connected to each of the light-emitting units arranged along a first direction, and a set of the second signal lines is electrically connected to each of the light-emitting units arranged along a second direction, the first direction being different from the second direction;
wherein a functional portion is provided in a region enclosed by at least part of adjacent first signal lines and at least at least part of adjacent second signal lines, and the functional portion is a through hole penetrating through the backplane.

In some embodiments, a set of the first signal lines includes a plurality of first signal lines, and at least one first signal line of the set of the first signal lines includes a plurality of first bending structures and a plurality of second bending structures, wherein the plurality of first bending structures and the plurality of second bending structures are alternately arranged one by one, and an opening of the first bending structure is oriented in an opposite direction to an opening of the second bending structure;
wherein the opening of the first bending structure faces the functional portion.

In some embodiments, at least one of the plurality of light-emitting portions of the light-emitting unit is electrically connected to the first signal line;
the opening of the second bending structure faces the light-emitting unit.

In some embodiments, the plurality of light-emitting portions include a first light-emitting portion, and the backplane is further integrated with a first pad group electrically connected to the first light-emitting portion and a driving pad group electrically connected to the driving portion; wherein

the first pad group includes a first electrode pad and a second electrode pad, wherein the first electrode pad is electrically connected to the second bending structure; and the driving pad group includes a first signal output pad corresponding to the first pad group, wherein the first signal output pad is electrically connected to the second electrode pad in the first pad group.

In some embodiments, the plurality of light-emitting portions further include a second light-emitting portion and a third light-emitting portion, and the backplane is further integrated with a second pad group electrically connected to the second light-emitting portion and a third pad group electrically connected to the third light-emitting portion; wherein
the second pad group includes a third electrode pad and a fourth electrode pad, and the driving pad group further includes a second signal output pad corresponding to the second pad group, wherein the second signal output pad is electrically connected to the fourth electrode pad in the second pad group;
the third pad group includes a fifth electrode pad and a sixth electrode pad, and the driving pad group further includes a third signal output pad corresponding to the third pad group, wherein the third signal output pad is electrically connected to the sixth electrode pad in the third pad group.

In some embodiments, the first electrode pad and the third electrode pad are a same pad; or
the first electrode pad and the fifth electrode pad are a same pad; or
the third electrode pad and the fifth electrode pad are a same pad; or
the first electrode pad, the third electrode pad, and the fifth electrode pad are a same pad.

In some embodiments, a set of the first signal lines includes: a data signal line and a first common electrode signal line; the first common electrode signal line including the first bending structure and the second bending structure; and the driving pad group further includes a first access pad electrically connected to the data signal line; wherein
the first access pad and at least two signal output pads are arranged in one column, wherein the at least two signal output pads are at least two of the first signal output pad, the second signal output pad, and the third signal output pad.

In some embodiments, the first access pad and the at least two signal output pads are arranged along the first direction;

the second electrode pad, the fourth electrode pad, and the sixth electrode pad are arranged along the first direction.

In some embodiments, an orthographic projection of the data signal on a plane where the backplane is disposed is overlapped with orthographic projections of the first access pad and the signal output pads arranged in one column along the first direction on the plane where the backplane is disposed.

In some embodiments, the backplane is further integrated with a bending trace, and two ends of the bending trace are electrically connected to the third signal output pad and the sixth electrode pad, respectively;
the backplane is provided with a first via hole for connecting the first access pad and the data signal line, wherein a first portion of the bending trace is disposed on a side of the first via hole away from the first access pad in the first direction, and a second portion and a third portion of the bending trace are respectively disposed on two sides of the first via hole in the second direction; wherein the third signal output pad, the second portion of the bending trace, the first portion of the bending trace, the third portion of the bending trace, and the sixth electrode pad are sequentially connected in series.

In some embodiments, the first access pad, the first signal output pad and the second signal output pad are arranged as a first column of driving pads along the first direction;
the third signal output pad is disposed on a side of the first column of driving pads away from the plurality of light-emitting portions;
the driving pad group further includes a ground pad, and the backplane is further provided with a second via hole for connecting the ground pad and a ground terminal of the backplane, wherein the first portion of the bending trace and a fourth portion of the bending trace are respectively disposed on two sides of the second via hole in the first direction, and the third portion of the bending trace is disposed on a side of the second via hole away from the ground pad in the second direction; wherein the third signal output pad, the fourth portion of the bending trace, the second portion of the bending trace, the first portion of the bending trace, the third portion of the bending trace, and the sixth electrode pad are sequentially connected in series.

In some embodiments, the driving pad group further includes a second access pad and a ground pad, the second access pad being electrically connected to the second signal line, and the ground pad being electrically connected to a ground terminal of the backplane;
in one driving pad group, the first access pad, the first signal output pad and the second signal output pad are arranged as a first column of driving pads along the first direction, and the ground pad, the third signal output pad and the second access pad are arranged as a second column of driving pads along the first direction;
the first pad group, the second pad group and the third pad group corresponding to one of the light-emitting units are all disposed on a side of the first column of driving pads away from the second column of driving pads.

In some embodiments, in the first pad group, the second pad group and the third pad group corresponding to one of the light-emitting units, the first electrode pad, the third electrode pad and the fifth electrode pad are arranged as a first column of electrode pads along the first direction, the second electrode pad, the fourth electrode pad and the sixth electrode pad are arranged as a second column of electrode pads along the first direction, wherein the first column of electrode pads is disposed on a side of the second column of electrode pads away from the first column of driving pads.

In some embodiments, the first access pad and the ground pad are arranged adjacently in the second direction, the third signal output pad is disposed between the ground pad and the second access pad, and the second access pad is closer to the second signal line electrically connected to the second access pad than the ground pad is.

In some embodiments, the first electrode pad, the third electrode pad and the fifth electrode pad are arranged in one column along the first direction, and the first electrode pad is disposed between the third electrode pad and the fifth electrode pad;
a set of the first signal lines further includes a second common electrode signal line, the second common electrode signal line including the first bending structure and the second bending structure;
wherein the first electrode pad is electrically connected to the second bending structure in the first common electrode signal line, and the third electrode pad and the fifth electrode pad are electrically connected to the second common electrode signal line.

In some embodiments, the second common electrode signal line is closer to the plurality of light-emitting portions of the light-emitting unit than the first common electrode signal line is;
a bending degree of the first bending structure in the second common electrode signal line is less than a bending degree of the first bending structure in the first common electrode signal line; and a bending degree of the second bending structure in the second common electrode signal line is less than a bending degree of the second bending structure in the first common electrode signal line.

In some embodiments, the first light-emitting portion is a red light-emitting portion for emitting red light, the second light-emitting portion is one of a green light-emitting portion for emitting green light and a blue light-emitting portion for emitting blue light, and the third light-emitting portion is the other one of the green light-emitting portion and the blue light-emitting portion.

In some embodiments, the at least one first signal line includes: a plurality of first extension portions, a plurality of second extension portions, and a first connection portion for connecting the first extension portion and the second extension portion; wherein the plurality of first extension portions and the plurality of second extension portions are alternately arranged one by one, an extension direction of the first extension portion is parallel to an extension direction of the second extension portion, the first connection portion is disposed between the first extension portion and the second extension portion that are adjacent to each other, the first extension portion is connected to one end of the first connection portion, and the second extension portion is connected to other end of the first connection portion;
the first extension portion and two first connection portions connected to two ends of the first extension portion constitute one first bending structure, and the second extension portion and two first connection portions connected to two ends of the second extension portion constitute one second bending structure.

In some embodiments, a part of the functional portion extends to a region enclosed by the first bending structure and an extended line of the second extension portion at a position where the first bending structure is disposed.

In some embodiments, a set of the second signal lines includes at least one second signal line, and the at least one second signal line includes a plurality of third bending structures and a plurality of fourth bending structures; wherein the plurality of third bending structures and the plurality of fourth bending structures are alternately arranged one by one, and an opening of the third bending structure is oriented in an opposite direction to an opening of the fourth bending structure;
wherein the opening of the third bending structure faces the functional portion, and the opening of the fourth bending structure faces the light-emitting unit.

In some embodiments, the backplane is provided with a device fixing region and a sound transmission region surrounding the device fixing region; wherein
in the sound transmission region, the through hole is provided in a region enclosed by adjacent first signal lines and adjacent second signal lines; and in the device fixing region, no through hole is provided in a region enclosed by adjacent first signal lines and adjacent second signal lines.

In some embodiments, the display panel further includes: a driving control module fixed on a back surface of the display panel, wherein the driving control module is disposed in the device fixing region, and the driving control module is configured to send a driving signal to the first signal line and the second signal line.

In some embodiments, the backplane is a printed circuit board; or
the backplane includes a substrate, wherein the first signal line and the second signal line are disposed on a side of the substrate, and the substrate is made of glass.

According to some embodiments of the present disclosure, a display module is provided. The display module includes: a box, a display panel disposed on a side of the box, and a stereo disposed between the box and the display panel, wherein a sound emitting surface of the stereo faces the display panel; and the display panel is the display panel described in the above aspect.

In some embodiments, the display module further includes: a signal access circuit board disposed between the box and the display panel, wherein the signal access circuit board is configured to be electrically connected to a driving control module in the display panel; wherein
a surface where the signal access circuit board is disposed intersects with a surface where the display panel is disposed.

In some embodiments, a plurality of display panels are provided, and the plurality of display panels are arranged in an array;
the box has an accommodation cavity, at least one signal access circuit board is provided, and the at least one signal access circuit board and the stereo are disposed in the accommodation cavity;
wherein in a direction parallel to the sound emitting surface of the stereo, the signal access circuit board is disposed on at least one side of the stereo in the accommodation cavity.

In still another aspect, a display system is provided. The display system includes: a plurality of first display modules spliced with each other, wherein the first display module is the display module described in the above aspect;
the display system further including: a plurality of second display modules spliced with each other, the second display module being spliced with the first display module; wherein the second display module includes a plurality of passive display panels spliced with each other.

In some embodiments, the display system further includes: a control device electrically connected to the first display modules and the second display modules; wherein
the control device is configured to: divide, based on position information of each of the first display modules and position information of each of the second display modules, an original video source to be displayed into a first video source corresponding to the first display module and a second video source corresponding to the second display module, and send a corresponding first video source to each of the first display modules, and send a corresponding second video source to each of the second display modules.

### BRIEF DESCRIPTION OF DRAWINGS

For clearer descriptions of the technical solutions in the embodiments of the present disclosure, the following briefly introduces the accompanying drawings required for describing the embodiments. The accompanying drawings in the following descriptions show merely some embodiments of the present disclosure, and persons of ordinary skill in the art may still derive other drawings from these accompanying drawings without creative effort.

FIG. 1 is a top view of a display panel according to some embodiments of the present disclosure;

FIG. 2 is a partial enlarged view of the display panel shown in FIG. 1 at position A;

FIG. 3 is a top view of a backplane according to some embodiments of the present disclosure;

FIG. 4 is a partial enlarged view of the backplane shown in FIG. 3 at position B;

FIG. 5 is a schematic structural diagram of a first signal line according to some embodiments of the present disclosure;

FIG. 6 is a schematic structural diagram of another first signal line according to some embodiments of the present disclosure;

FIG. 7 is a partial enlarged view of the backplane shown in FIG. 4 at position C;

FIG. 8 is a schematic diagram after a light-emitting unit is disposed on the backplane shown in FIG. 7;

FIG. 9 is a schematic structural diagram of a second signal line according to some embodiments of the present disclosure;

FIG. 10 is a schematic structural diagram of another second signal line according to some embodiments of the present disclosure;

FIG. 11 is a top view of another display panel according to some embodiments of the present disclosure;

FIG. 12 is a top view of a display module according to some embodiments of the present disclosure;

FIG. 13 is an exploded view of the display module shown in FIG. 12; and

FIG. 14 is a schematic structural diagram of a display system according to some embodiments of the present disclosure.

### DETAILED DESCRIPTION

To make the objectives, technical solutions and advantages of the present disclosure clearer, the embodiments of the present disclosure will be further described in detail below with reference to the accompanying drawings.

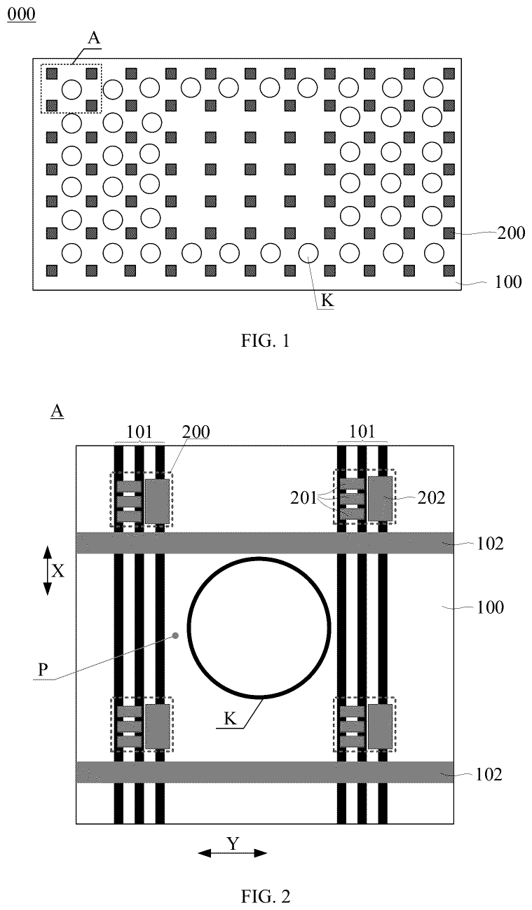

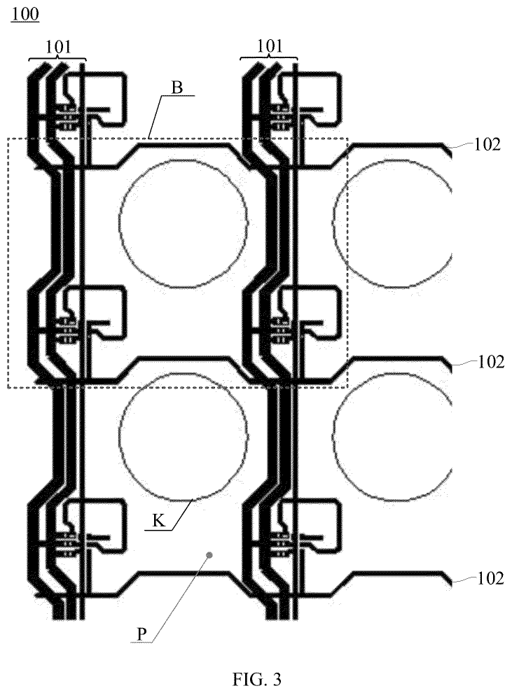

Referring to FIG. 1 and FIG. 2, FIG. 1 is a top view of a display panel according to some embodiments of the present disclosure, and FIG. 2 is a partial enlarged view of the display panel shown in FIG. 1 at position A. The display panel 000 includes a backplane 100 and a plurality of light-emitting units 200.

The plurality of light-emitting units 200 in the display panel 000 are disposed on a side of the backplane 100, and the plurality of light-emitting units 200 are arranged in an array on the side of the backplane 100. Each light-emitting unit 200 includes a driving portion 202 and a plurality of light-emitting portions 201 that are fixed on the backplane 100. Here, the light-emitting portion 201 in the light-emitting unit 200 is an LED chip. It should be noted that the LED chip is an LED chip with an ordinary size, which may be a mini light-emitting diode (mini LED) chip, or may also be a micro light-emitting diode (micro LED) chip. The driving portion 202 in the light-emitting unit 200 is a driving chip. Each light-emitting unit 200 is provided with a driving portion 202, and the driving portion 202 is electrically connected to each light-emitting portion 201 in the light-emitting unit 200. For example, the plurality of light-emitting portions 201 in the light-emitting unit 200 are independently packaged and fixed on the backplane 100. For another example, the plurality of light-emitting portions 201 in the light-emitting unit 200 are disposed as a whole in one integrated chip, that is, the plurality of light-emitting portions 201 are jointly packaged into one light-emitting chip, and the light-emitting chip is fixed on the backplane 100.

In the light-emitting unit 200, the light-emitting state and brightness of each light-emitting portion 201 can be independently controlled through the driving portion 202. Therefore, the display panel 000 provided in the embodiments of the present disclosure is an active display panel.

A plurality of sets of first signal lines 101 and a plurality of sets of second signal lines 102 are integrated in the backplane 100 of the display panel 000. A set of first signal lines 101 includes at least two first signal lines 101. For example, a set of first signal lines 101 includes three first signal lines 101. A set of second signal lines 102 includes at least one second signal line 102. For example, a set of second signal lines 102 includes one second signal line 102.

A set of first signal lines 101 is electrically connected to each of the light-emitting units 200 arranged along a first direction X; and a set of second signal lines 102 is electrically connected to each of the light-emitting units 200 arranged along a second direction Y. Here, the first direction X is different from the second direction Y, for example, the first direction X is perpendicular to the second direction Y.

For example, an extension surface of the backplane 100 is a plane or a curved surface, and the extension surface of the backplane 100 is defined as a surface of the side, provided with the light-emitting units 200, of the backplane. For example, in the case that the extension surface of the backplane 100 is a plane, the first direction X is an extension direction of a straight line parallel to the extension surface of the backplane 100, the second direction Y is an extension direction of another straight line parallel to the extension surface of the backplane 100, and the two straight lines are not parallel. For another example, in the case that the extension surface of the backplane 100 is a curved surface, the first direction X is an extension direction of a curve conformal to the extension surface of the backplane 100, the second direction Y is an extension direction of another curve conformal to the extension surface of the backplane 100, and the two curves are not parallel.

For example, the plurality of light-emitting units 200 are arranged in a plurality of rows and a plurality of columns along the first direction X and the second direction Y, the light-emitting units 200 in each row of light-emitting units 200 are arranged along the second direction Y, and the light-emitting units 200 in each column of light-emitting units 200 are arranged along the first direction X. Therefore, a set of first signal lines 101 is electrically connected to one column of light-emitting units 200, and a set of second signal lines 102 is electrically connected to one row of light-emitting units 200.

A functional portion is provided in a region enclosed by at least part of the adjacent first signal lines 101 and at least part of the adjacent second signal lines 102.

For example, in the backplane 100 of the display panel 000, two adjacent sets of first signal lines 101 and two adjacent sets of second signal lines 102 are configured to enclose a functional region P. The backplane 100 has a plurality of functional regions P arranged in an array, and at least part of the functional regions P in the backplane 100 are provided with functional portions. In a possible situation, the functional portion is a through hole K. In this situation, through holes K are distributed in the backplane 100 of the display panel 000, and the through holes K serve as sound transmission holes. In this way, even if a stereo is arranged on the back surface of the display panel 000, sound from the stereo can also be transmitted out from the sound transmission holes in the display panel 000, thereby ensuring that the display panel 000 does not shield the sound from the stereo. Therefore, the display panel 000 can be used as an acoustically transparent display panel, and the sound from the stereo arranged on the back surface of the display panel 000 can be directly transmitted out from the display surface of the display panel 000. Thus, the display panel 000 has both a display function and a sound transmission function, which effectively enriches the functions of the display panel 000, such that the display panel 000 has better effects in use.

In summary, the display panel provided in the embodiments of the present disclosure includes a backplane and a plurality of light-emitting units. In the backplane of the display panel, a through hole penetrating through the backplane is provided in a region enclosed by at least part of the adjacent first signal lines and at least part of the adjacent second signal lines. In this way, through holes are distributed in the backplane of the display panel, and these through holes can serve as sound transmission holes. Even if the stereo is arranged on the back surface of the display panel, the sound from the stereo can be transmitted out from the sound transmission holes in the display panel, thereby ensuring that the display panel does not shield the sound from the stereo. Therefore, the display panel can be used as an acoustically transparent display panel, and the sound from the stereo arranged on the back surface of the display panel can be directly transmitted out from the display surface of the display panel. Thus, the display panel has both a display function and a sound transmission function, which effectively enriches the functions of the display panel, such that the display panel has better effects in use.

In another possible situation, the through holes K serve as light transmission holes, such that light on one side of the display panel 000 can pass through the through holes K to reach the other side of the display panel 000 and be emitted out, thereby implement transparent display. In this situation, the through holes K not only allow a user to see a display image presented on the display panel 000, but also allow the user to see an image behind the display panel 000, thereby achieving characteristic viewing effects.

In still another possible situation, the through holes K serve as light transmission holes, such that light on one side of the display panel 000 can pass through the through holes K to reach the other side of the display panel 000 and be emitted out. Therefore, an image acquisition unit (such as a camera and a webcam) may be installed at a non-display side of the display panel 000, such that an under-screen image acquisition function can be implemented in the display region.

It should be noted that, in other optional implementations, no through hole is formed in the functional region P, and the functional region P is used to implement other functions. For example, the backplane 100 includes a transparent substrate for target light. In the functional region P, since the first signal line 101 and the second signal line 102 do not pass through the functional region P, the functional region P can transmit the target light, thereby implementing transparent display. The target light is visible light, and the transparent substrate for the target light is a glass substrate. Other functional portions may also be provided in the functional region P, such that the display panel can have corresponding functions. For example, the functional portion disposed in the functional region P is a light sensor, and the display panel further has a function of sensing external light. For example, the functional region P may also be provided with a fingerprint recognition unit, an NFC unit, an antenna unit, and the like.

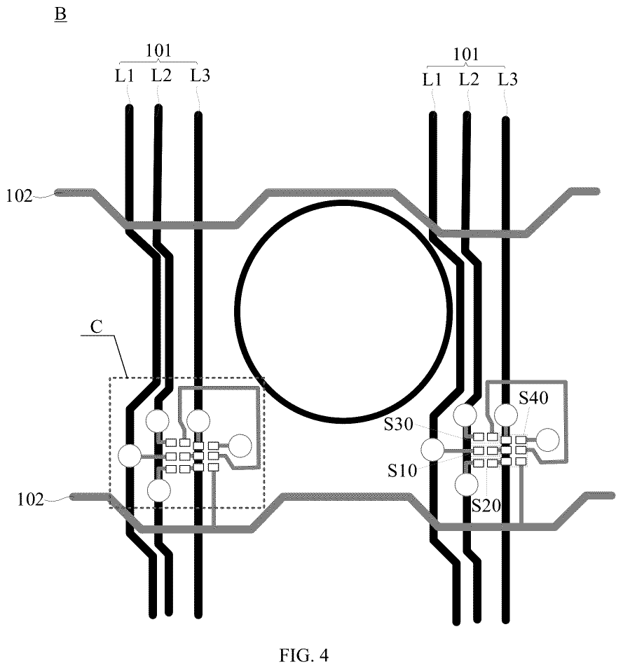

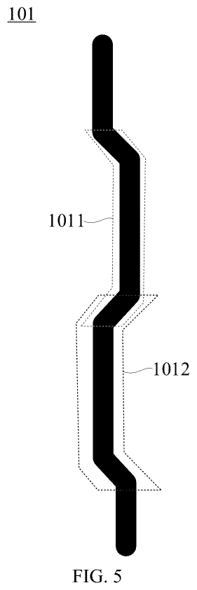

In order to show the structure of the backplane 100 of the display panel 000 more clearly, please refer to FIG. 3 and FIG. 4, FIG. 3 is a top view of a backplane according to some embodiments of the present disclosure, and FIG. 4 is a partial enlarged view of the backplane shown in FIG. 3 at position B. A set of first signal lines 101 in the backplane 100 includes a plurality of first signal lines 101. To show the structure of the first signal line 101 integrated in the backplane 100 more clearly, please refer to FIG. 5, and FIG. 5 is a schematic structural diagram of a first signal line according to some embodiments of the present disclosure. At least one first signal line 101 in a set of first signal lines 101 includes a plurality of first bending structures 1011 and a plurality of second bending structures 1012. In the first signal line 101, the plurality of first bending structures 1011 and the plurality of second bending structures 1012 are alternately arranged one by one, and an opening of the first bending structure 1011 is oriented in an opposite direction to an opening of the second bending structure 1012. For example, the opening of the first bending structure 1011 faces the left side of the first signal line 101, and the opening of the second bending structure 1012 faces the right side of the first signal line 101.

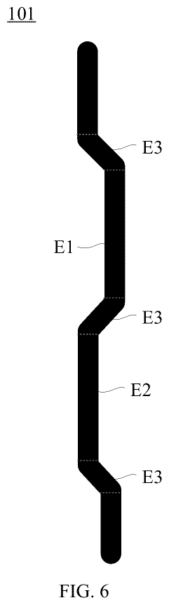

For example, referring to FIG. 6, and FIG. 6 is a schematic structural diagram of another first signal line according to some embodiments of the present disclosure. At least one first signal line 101 includes a plurality of first extension portions E1, a plurality of second extension portions E2, and a first connection portion E3 for connecting the first extension portion E1 and the second extension portion E2. Here, the plurality of first extension portions E1 and the plurality of second extension portions E2 in the first signal line 101 are alternately arranged one by one, and the extension directions of the plurality of first extension portions E1 are parallel to the extension directions of the plurality of second extension portions E2. For example, the extension direction of the first extension portion E1 and the extension direction of the second extension portion E2 are both parallel to the first direction X. The first connection portion E3 of the first signal line 101 is disposed between the first extension portion E1 and the second extension portion E2, the first extension portion E1 is connected to one end of the first connection portion E3, and the second extension portion E2 is connected to the other end of the first connection portion E3.

The extension direction of the first connection portion E3 intersects with the extension direction of the first extension portion E1, and intersects with the extension direction of the second extension portion E2. In this case, the first extension portion E1 and two first connection portions E3 connected to two ends of the first extension portion E1 constitute one first bending structure 1011; and the second extension portion E2 and two first connection portions E3 connected to two ends of the second extension portion E2 constitute one second bending structure 1012.

In the present disclosure, the opening of the first bending structure 1011 in the first signal line 101 faces the functional portion. In a possible implementation, in the case that the functional portion is a through hole K, a part of the through hole K disposed in the functional region P extends to a region enclosed by the first bending structure 1011. Here, the region enclosed by the first bending structure 1011 refers to a region enclosed by the first bending structure 1011 and an extended line of the second extension portion E2 which is at the position where the first bending structure 1011 is disposed. In this way, by providing the first bending structure 1011 in the first signal line 101 and making a part of the through hole K extend to the region enclosed by the first bending structure 1011, the area of the opening of the through hole K formed in the functional region P can be effectively increased and thus the through hole K has a larger size, which is more helpful for the sound from the stereo arranged on the back surface of the display panel 000 to pass through the through hole K, thereby effectively reducing the energy loss when the stereo makes sound.

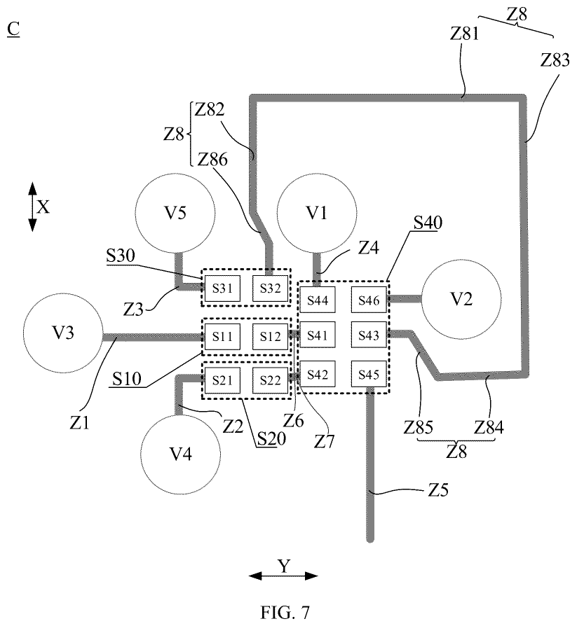

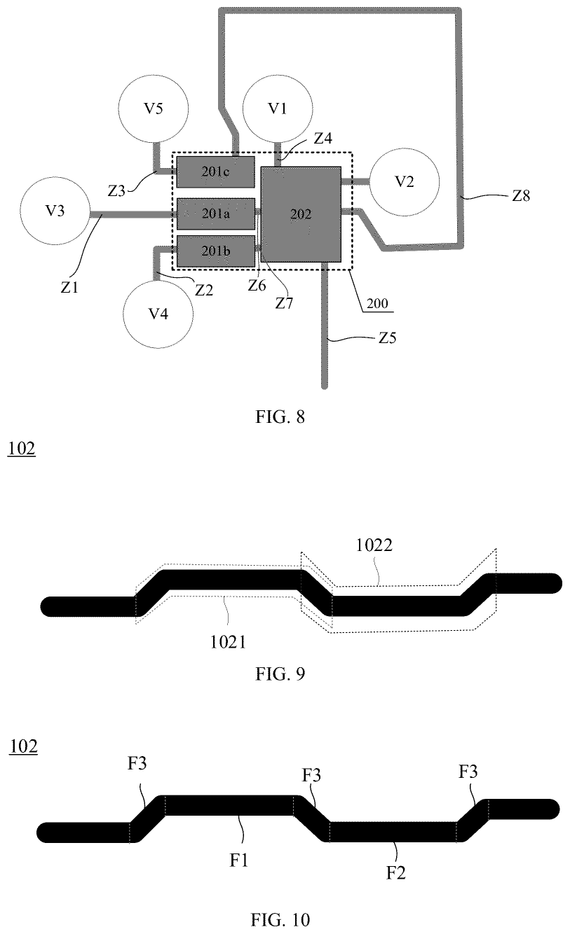

In the embodiments of the present disclosure, as shown in FIG. 7 and FIG. 8, FIG. 7 is a partial enlarged view of the backplane shown in FIG. 4 at position C, and FIG. 8 is a schematic diagram after a light-emitting unit is disposed on the backplane shown in FIG. 7. At least one light-emitting portion 201 of the light-emitting unit 200 in the display panel 000 is electrically connected to the first signal line 101. For example, for the light-emitting unit 200 in the display panel 000, each light-emitting portion 201 of the light-emitting unit 200 is electrically connected to one part of the first signal lines 101 in a corresponding set of first signal lines 101, and the driving portion 202 of the light-emitting unit 200 is electrically connected to the other part of the first signal lines 101 in the corresponding set of first signal lines 101 and electrically connected to a corresponding set of second signal lines 102.

In the present disclosure, the opening of the second bending structure 1012 in the first signal line 101 faces the light-emitting unit 200. In this way, it can be ensured that the light-emitting unit 200 in the display panel 000 does not occupy too much of the functional region P, and it can be further ensured that the through hole K of a larger size can be provided in the functional region P.

In some embodiments, as shown in FIG. 8, the light-emitting unit 200 includes three light-emitting portions 201, and the three light-emitting portions 201 are respectively configured to emit red light, green light and blue light. For example, the plurality of light-emitting portions 201 of the light-emitting unit 200 are a first light-emitting portion 201a, a second light-emitting portion 201b, and a third light-emitting portion 201c, respectively. Here, the first light-emitting portion 201a is a red light-emitting portion for emitting red light, the second light-emitting portion 201b is one of a green light-emitting portion for emitting green light and a blue light-emitting portion for emitting blue light, and the third light-emitting portion 201c is the other one of the green light-emitting portion and the blue light-emitting portion. The embodiments of the present disclosure are illustrated by taking an example where the second light-emitting portion 201b is a green light-emitting portion, and the third light-emitting portion 201c is a blue light-emitting portion.

As shown in FIG. 4, FIG. 7 and FIG. 8, the backplane 100 of the display panel 000 is further integrated with a first pad group S10 electrically connected to the first light-emitting portion 201a, a second pad group S20 electrically connected to the second light-emitting portion 201b, a third pad group S30 electrically connected to the third light-emitting portion 201c, and a driving pad group S40 electrically connected to the driving portion 202 of the light-emitting unit 200.

The first pad group S10 corresponding to the first light-emitting portion 201a includes a first electrode pad S11 and a second electrode pad S12. Here, one of the first electrode pad S11 and the second electrode pad S12 is an anode pad, and the other one of the first electrode pad S11 and the second electrode pad S12 is a cathode pad. The first light-emitting portion 201a has an anode pin and a cathode pin. The anode pin and the cathode pin of the first light-emitting portion 201a are welded on the first pad group S10 in a welding manner, such that the first light-emitting portion 201a is fixed on the substrate 100, and is electrically connected to the backplane 100 through the first electrode pad S11 and the second electrode pad S12 in the first pad group S10.

The second pad group S20 corresponding to the second light-emitting portion 201b includes a third electrode pad S21 and a fourth electrode pad S22. Here, one of the third electrode pad S21 and the fourth electrode pad S22 is an anode pad, and the other one of the third electrode pad S21 and the fourth electrode pad S22 is a cathode pad. The second light-emitting portion 201b has an anode pin and a cathode pin. The anode pin and the cathode pin of the second light-emitting portion 201b are welded on the second pad group S20 in a welding manner, such that the second light-emitting portion 201b is fixed on the substrate 100, and is electrically connected to the backplane 100 through the third electrode pad S21 and the fourth electrode pad S22 in the second pad group S20.

The third pad group S30 corresponding to the third light-emitting portion 201c includes a fifth electrode pad S31 and a sixth electrode pad S32. Here, one of the fifth electrode pad S31 and the sixth electrode pad S32 is an anode pad, and the other one of the fifth electrode pad S31 and the sixth electrode pad S32 is a cathode pad. The third light-emitting portion 201c has an anode pin and a cathode pin. The anode pin and the cathode pin of the third light-emitting portion 201c are welded on the third pad group S30 in a welding manner, such that the third light-emitting portion 201c is fixed on the substrate 100, and is electrically connected to the backplane 100 through the fifth electrode pad S31 and the sixth electrode pad S32 in the third pad group S30.

The driving pad group S40 corresponding to the driving portion 202 includes a first signal output pad S41, a second signal output pad S42, a third signal output pad S43, a first access pad S44, a second access pad S45, and a ground pad 46. The light-emitting portion 201 has six pins, and the six pins of the light-emitting portion 201 are welded on the driving pad group S40 in a welding manner, such that the driving portion 202 is fixed on the substrate 100, and is electrically connected to the backplane 100 through the six pads in the driving pad group S40.

The first signal output pad S41 in the driving pad group S40 is electrically connected to the second electrode pad S12 in the first pad group S10; the second signal output pad S42 in the driving pad group S40 is electrically connected to the fourth electrode pad S22 in the second pad group S20; and the third signal output pad S43 in the driving pad group S40 is electrically connected to the sixth electrode pad S32 in the third pad group S30. In this case, the driving portion 202 of the light-emitting unit 200 is electrically connected to the respective light-emitting portions 201 through the pads arranged in the backplane 100.

In the present disclosure, the first electrode pad S11 in the first pad group S10, the third electrode pad S21 in the second pad group S20, and the fifth electrode pad S31 in the third pad group S30 are all connected to part of the first signal lines 101 in a set of first signal lines 101.

In a possible situation, the first electrode pad S11, the third electrode pad S21 and the fifth electrode pad S31 are connected to three first signal lines 101, respectively.

In another possible situation, two of the first electrode pad S11, the third electrode pad S21 and the fifth electrode pad S31 are electrically connected to the same first signal line 101, and the other electrode pad is connected to another first signal line 101.

For example, the first electrode pad S11 and the fifth electrode pad S31 are the same pad, and this pad is electrically connected to one first signal line 101, and the third electrode pad S21 is electrically connected to another first signal line 101. Alternatively, the first electrode pad S11 and the third electrode pad S21 are the same pad, and this pad is electrically connected to one first signal line 101, and the fifth electrode pad S31 is electrically connected to another first signal line 101. Alternatively, the third electrode pad S21 and the fifth electrode pad S31 are the same pad, and this pad is electrically connected to one first signal line 101, and the first electrode pad S11 is electrically connected to another first signal line 101.

In this way, in the three light-emitting portions 201 of the light-emitting unit 200, two light-emitting portions 201 of the three light-emitting portions 201 are simultaneously connected to the same first signal line 101, and this first signal line provides a common voltage signal to the two light-emitting portions 201 of the light-emitting unit 200 simultaneously; and the other light-emitting portion 201 of the three light-emitting portions 201 is connected to another first signal line 101, and this first signal line provides another common voltage signal to the other light-emitting portion 201 of the light-emitting unit 200.

Certainly, in other possible implementations, the two electrode pads connected to the same first signal line 101 are two independent pads, and the two independent pads are electrically connected to the same first signal line 101, which is not limited in the embodiments of the present disclosure.

In another possible situation, the first electrode pad S11, the third electrode pad S21 and the fifth electrode pad S31 are all connected to the same first signal line 101.

For example, the first electrode pad S11, the third electrode pad S21 and the fifth electrode pad S31 are the same pad, and this pad is electrically connected to one first signal line 101. In this way, the first light-emitting portion 201a, the second light-emitting portion 201b and the third light-emitting portion 201c of the light-emitting unit 200 are simultaneously connected to the same first signal line 101, and the first signal line 101 provides a common voltage signal to all the light-emitting portions 201 of the light-emitting unit 200 simultaneously.

Certainly, in other possible implementations, the first electrode pad S11, the third electrode pad S21 and the fifth electrode pad S31 are three independent pads, and the three independent pads are electrically connected to the same first signal line 101. In this way, it can be ensured that the first light-emitting portion 201a, the second light-emitting portion 201b and the third light-emitting portion 201c of the light-emitting unit 200 are simultaneously connected to the same first signal line 101, which is not limited in the embodiments of the present disclosure.

It should be noted that the drawings in the embodiments of the present disclosure are all schematically illustrated by taking that the first electrode pad S11, the third electrode pad S21 and the fifth electrode pad S31 are three independent pads as an example.

It should also be noted that, in the light-emitting unit 200, the light-emitting characteristic of the red light-emitting portion when emitting red light is greatly different from the light-emitting characteristic of the green light-emitting portion when emitting green light, and is also greatly different from the light-emitting characteristic of the blue light-emitting portion when emitting blue light, and the light-emitting characteristic of the green light-emitting portion when emitting green light is slightly different from the light-emitting characteristic of the blue light-emitting portion when emitting blue light. Therefore, the green light-emitting portion and the blue light-emitting portion are connected to the same first signal line 101, and the red light-emitting portion is connected to another first signal line 101. In this case, assuming that in the light-emitting unit 200, the first light-emitting portion 201a is a red light-emitting portion for emitting red light, the second light-emitting portion 201b is a green light-emitting portion for emitting green light, and the third light-emitting portion 201c is a blue light-emitting portion for emitting blue light, then the third electrode pad S21 in the second pad group S20 corresponding to the second light-emitting portion 201b and the fifth electrode pad S31 in the third pad group S30 corresponding to the third light-emitting portion 201c are electrically connected to the same first signal line 101, and the first electrode pad S11 in the first pad group S10 corresponding to the first light-emitting portion 201a is electrically connected to another first signal line 101.

In the embodiments of the present disclosure, the first electrode pad S11 in the first pad group S10 corresponding to the first light-emitting portion 201a is electrically connected to the second bending structure 1012 in the first signal line 101. In this case, the first light-emitting portion 201a is electrically connected to the second bending structure 1012 through the first electrode pad S11 in the first pad group S10, such that the first light-emitting portion 201a can be connected to the first signal line 101 having the second bending structure 1012.

For example, the orthographic projections of the driving portion 202 and light-emitting portions 201 of the light-emitting unit 200 on the plane where the backplane 100 is disposed are overlapped with the orthographic projection of the corresponding set of first signal lines 101 on the plane where the backplane 100 is disposed. Therefore, in the case that the opening of the second bending structure 1012 in the first signal line 101 faces the light-emitting unit 200, and the first light-emitting portion 201a of the light-emitting unit 200 is connected to the first signal line 101 through the second bending structure 1012, the space of the functional region P occupied by the light-emitting unit 200 can be further reduced, thereby further increasing the size of the through hole K disposed in the functional region P.

In some embodiments, as shown in FIG. 4, a set of first signal lines 101 in the backplane 100 includes a first common electrode signal line L1. The first electrode pad S11 in the first pad group S10 in the backplane 100 is electrically connected to the first common electrode signal line L1. For example, the first common electrode signal line L1 includes a first bending structure 1011 and a second bending structure 1012. As shown in FIG. 7, the first electrode pad S11 in the first pad group S10 in the backplane 100 is electrically connected to the second bending structure 1012 in the first common electrode signal line L1, such that the first light-emitting portion 201a corresponding to the first pad group S10 is connected to the first common electrode signal line L1. For example, a first connection signal line Z1 is further integrated in the backplane 100, and the first electrode pad S11 is electrically connected to the second bending structure 1012 in the first common electrode signal line L1 through the first connection signal line Z1. Here, the first light-emitting portions 201a of the light-emitting units 200 arranged in one column in the first direction X are connected to the same first common electrode signal line L1 through the corresponding first electrode pads S11, such that the first common electrode signal line L1 can provide the same first common voltage signal to each of the first light-emitting portions 201a of the light-emitting units 200 in one column.

A set of first signal lines 101 in the backplane 100 further includes a second common electrode signal line L2. The third electrode pad S21 and the fifth electrode pad S31 are simultaneously electrically connected to the second common electrode signal line L2. Preferably, the third electrode pad S21 in the second pad group S20 in the backplane 100 is electrically connected to the second bending structure 1012 in the second common electrode signal line L2, and the fifth electrode pad S31 in the third pad group S30 in the backplane 100 is also electrically connected to the second bending structure 1012 in the second common electrode signal line L2. In the present disclosure, the second common electrode signal line L2 also includes a first bending structure 1011 and a second bending structure 1012. In this way, the third electrode pad S21 and the fifth electrode pad S31 are both connected to the second common electrode signal line L2 simultaneously by being electrically connected to the second bending structure 1012. For example, a second connection signal line Z2 and a third connection signal line Z3 are integrated in the backplane 100, the third electrode pad S21 is electrically connected to the second bending structure 1012 in the second common electrode signal line L2 through the second connection signal line Z2, and the fifth electrode pad S31 is electrically connected to the second bending structure 1012 in the second common electrode signal line L2 through the third connection signal line Z3. Here, the second light-emitting portions 201b and the third light-emitting portions 201c of the light-emitting units 200 arranged in one column in the first direction X are all connected to the same second common electrode signal line L2 through the corresponding third electrode pads S21 and the corresponding fifth electrode pads S31, such that the second common electrode signal line L2 can provide the same second common voltage signal to each of the second light-emitting portions 201b and each of the third light-emitting portions 201c of the light-emitting units 200 in one column.

It should be noted that the first common voltage signal and the second common voltage signal in the foregoing embodiments are both anode signals or cathode signals, and it should be ensured that volt values of the first common voltage signal and the second common voltage signal are different.

In some embodiments, a set of first signal lines 101 in the backplane 100 further includes a third common electrode signal line. Here, the third electrode pad S21 in the second pad group S20 in the backplane 100 is electrically connected to one of the second common electrode signal line L2 and the third common electrode signal line, and the fifth electrode pad S31 in the third pad group S30 in the backplane 100 is electrically connected to the other one of the second common electrode signal line L2 and the third common electrode signal line. In this way, voltages can be supplied to the second light-emitting portion 201b and the third light-emitting portion 201c, respectively.

It should be noted that the first common voltage signal, the second common voltage signal and the third common voltage signal in the foregoing embodiments are all anode signals or cathode signals. For example, the volt values of the first common voltage signal, the second common voltage signal and the third common voltage signal are different.

In the present disclosure, the first common electrode signal line L1 and the second common electrode signal line L2 extend along the same direction. In this way, the first bending structure 1011 and the second bending structure 1012 in the first common electrode signal line L1 are arranged in consistent with the first bending structure 1011 and the second bending structure 1012 in the second common electrode signal line L2. Therefore, the opening of the first bending structure 1011 in the first common electrode signal line L1 and the opening of the first bending structure 1011 in the second common electrode signal line L2 both face the through hole K; and the opening of the second bending structure 1012 in the first common electrode signal line L1 and the opening of the second bending structure 1012 in the second common electrode signal line L2 both face the light-emitting unit 200.

In some embodiments, the three light-emitting portions 201 of the light-emitting unit 200 are generally arranged in one column along the first direction X. Therefore, in the backplane 100, in the first pad group S10, the second pad group S20 and the third pad group S30 that correspond to one light-emitting unit 200, the first electrode pad S11 in the first pad group S10, the third electrode pad S21 in the second pad group S20, and the fifth electrode pad S31 in the third pad group S30 are arranged as a first column of electrode pads along the first direction X. Here, the first electrode pad S11 is disposed between the third electrode pad S21 and the fifth electrode pad S31. Correspondingly, in the backplane 100, the second electrode pad S12 in the first pad group S10, the fourth electrode pad S22 in the second pad group S20, and the sixth electrode pad S32 in the third pad group S30 are also arranged as a second column of electrode pads along the first direction X, and the second electrode pad S12 is disposed between the fourth electrode pad S22 and the sixth electrode pad S32.

In this case, the first signal lines 101 are disposed in a different layer from the various pads and connection signal lines in the backplane 100, and the various pads and connection signal lines are disposed in the same layer in the backplane 100. That is, in the backplane 100, an insulating layer is disposed between the conductive layer where the first signal lines 101 are disposed and the conductive layer where the pads are disposed, and the conductive layer where the pads are disposed and the conductive layer where the confection signal lines are disposed are the same conductive layer. Therefore, the pads can be electrically connected to the confection signal lines directly, for example, the first electrode pad S11 is electrically connected to the first connection signal line Z1 directly. The first common electrode signal line L1 in a set of first signal lines 101 and the first connection signal line Z1 are electrically connected to each other through a third via hole V3, the second common electrode signal line L2 in a set of first signal lines 101 and the second connection signal line Z2 are electrically connected to each other through a fourth via hole V4, and the second common electrode signal line L2 is further electrically connected to the third connection signal line Z3 through a fifth via hole V5. Here, the third via hole V3, the fourth via hole V4 and the fifth via hole V5 all penetrate through the insulating layer disposed between the conductive layer where the first signal lines 101 are disposed and the conductive layer where the pads are disposed. The via holes in the insulating layer have larger areas; and the first common electrode signal line L1 is electrically connected to the first electrode pad S11 through the third via hole V3 only, and the second common electrode signal line L2 is electrically connected to the third electrode pad S21 and the fifth electrode pad S31 through the fourth via hole V4 and the fifth via hole V5 respectively. Therefore, when the first electrode pad S11 is disposed between the third electrode pad S21 and the fifth electrode pad S31, the first connection signal line Z1 is also disposed between the second connection signal line Z2 and the third connection signal line Z3 in the first direction, and the fourth via hole V4 and the fifth via hole V5 are distributed on two sides of the third via hole V3 in the first direction X, such that the third via hole V3, the fourth via hole V4 and the fifth via hole V5 are distributed more compactly in the first direction X, which can effectively reduce the space occupied by a set of first signal lines 101 and thereby further increase the area of the functional region P.

In some embodiments, in a set of first signal lines 101, the second common electrode signal line L2 is closer to the plurality of light-emitting portions 201 of the light-emitting unit 200 than the first common electrode signal line L1 is. In this case, the first connection signal line Z1 is disposed between the fourth via hole V4 and the fifth via hole V5 in the first direction X, which can further improve the distribution compactness of the first signal lines 101 in the set of first signal lines 101.

Additionally, in the case that the second common electrode signal line L2 also includes the first bending structure 1011 and the second bending structure 1012, the bending degree of the first bending structure 1011 in the second common electrode signal line L2 is less than the bending degree of the first bending structure 1011 in the first common electrode signal line L1, and at least part of the first bending structure 1011 in the second common electrode signal line L2 is disposed in the region enclosed by the first bending structure 1011 in the first common electrode signal line L1. Similarly, the bending degree of the second bending structure 1012 in the second common electrode signal line L2 is less than the bending degree of the second bending structure 1012 in the first common electrode signal line L1, and at least part of the second bending structure 1012 in the second common electrode signal line L2 is disposed in the region enclosed by the second bending structure 1012 in the first common electrode signal line L1. In this way, it can be ensured that the distance between the first common electrode signal line L1 and the second common electrode signal line L2 in a set of first signal lines 101 is small, such that the first signal lines 101 in the set of first signal lines 101 are distributed more compactly.

In the embodiments of the present disclosure, a set of first signal lines 101 further includes a data signal line L3. It should be noted that FIG. 4 is illustrated by taking that the data signal line L3 is a signal line extending along the first direction X, and the data signal line L3 does not include the first bending structure 1011 and the second bending structure 1012 as an example. In other possible implementations, the data signal line L3 includes the first bending structure 1011 and the second bending structure 1012, which is not limited in the embodiments of the present disclosure. The data signal line L3 is electrically connected to the first access pad S44 in the driving pad group S40, such that the driving portion 202 corresponding to the driving pad group S40 is electrically connected to the data signal line L3. It should be noted that, in order to connect each light-emitting portion 201 of the light-emitting unit 200 to the corresponding common electrode signal line, it needs to be ensured that in the second direction Y, each light-emitting portion 201 of the light-emitting unit 200 is closer to the common electrode signal line than the driving portion 202 is. In a set of first signal lines 101, the second common electrode signal line L2 is closer to the plurality of light-emitting portions 201 of the light-emitting unit 200 than the first common electrode signal line L1 is. Therefore, in the present disclosure, in order to electrically connect the driving portion of the light-emitting unit 200 to the data signal line L3, in a set of first signal lines 101, the data signal line L3 is disposed on the side of the second common electrode signal line L2 away from the first common electrode signal line L1.

For example, a fourth connection signal line Z4 is further integrated in the backplane 100, and the first access pad S44 is electrically connected to the data signal line L3 through the fourth connection signal line Z4. Here, the driving portions 202 of the light-emitting units 200 arranged in one column in the first direction X are all electrically connected to the same data signal line L3 through the corresponding first access pads S44, such that the data signal line L3 provides the same data signal to the driving portions 202 of the light-emitting units 200 in one column. It should be noted that the first access pad S44 and the data signal line L3 are disposed in different layers. Therefore, the backplane 100 is provided with a first via hole V1 for connecting the first access pad S44 and the data signal line L3. For example, since the fourth connection signal line Z4 is disposed in the same layer as the first access pad S44, one end of the fourth connection signal line Z4 is electrically connected to the first access pad S44 directly, and the other end of the fourth connection signal line Z4 is electrically connected to the data signal line L3 through the first via hole V1.

In some embodiments, in the driving pad group S40, the first access pad S44 and at least two signal output pads are arranged in one column, and the at least two signal output pads in the driving pad group S40 are at least two of the first signal output pad S41, the second signal output pad S42 and the third signal output pad S43. For example, the first access pad S44 and the at least two signal output pads in the driving pad group S40 are arranged along the first direction X.

In this case, since the extension direction of the data signal line L3 is also parallel to the first direction X, the orthographic projection of the data signal line L3 on the plane where the backplane 100 is disposed is made to be overlapped with the orthographic projections of the first access pad S44 and the signal output pads that are arranged in one column along the first direction on the plane where the backplane 100 is disposed. In this way, it can be ensured that the distance between the data signal line L3 and the second common electrode signal line L2 is short in a set of first signal lines 101, such that the first signal lines 101 in the set of first signal lines 101 are distributed more compactly.

In the embodiments of the present disclosure, the second access pad S45 in the driving pad group S40 is electrically connected to the second signal line 102. Here, a set of second signal lines 102 usually includes only one second signal line 102, and the second signal line 102 is a power signal line, such that the driving portion 202 corresponding to the driving pad group S40 can be electrically connected to the power signal line. For example, a fifth connection signal line Z5 is further integrated in the backplane 100, and the second access pad S45 is electrically connected to the power signal line through the fifth connection signal line Z5. Here, the driving portions 202 of the light-emitting units 200 arranged in one row in the second direction Y are all electrically connected to the same power signal line through the corresponding second access pads S45, such that the power signal line can provide the same power signal to the driving portions 202 of the light-emitting units 200 in one row. It should be noted that the second access pad S45, the power signal line and the fifth connection signal line Z5 are disposed in the same layer. Thus, one end of the fifth connection signal line Z5 is electrically connected to the second access pad S45 directly, and the other end of the fifth connection signal line Z5 is electrically connected to the power signal line directly.

The ground pad S46 in the driving pad group S40 is electrically connected to a ground terminal of the backplane 100, such that the driving portion 202 corresponding to the driving pad group S40 is electrically connected to the ground terminal. Here, the driving portions 202 of all light-emitting units 200 in the display panel 000 are electrically connected to the ground terminal of the backplane 100, such that the ground terminal of the backplane 100 can provide the same ground signal to the driving portions 202 of all the light-emitting units 200 in the display panel 000. It should be noted that the ground pad S46 and the ground terminal of the backplane 100 are disposed in different layers. Therefore, the backplane 100 is provided with a second via hole V2 for connecting the ground pad S46 and the ground terminal of the backplane 100, and the ground pad S46 is electrically connected to the ground terminal of the backplane 100 through the second via hole V2.

In a possible implementation, in the driving pad group S40, the first access pad S44, the first signal output pad S41 and the second signal output pad S42 are arranged as a first column of driving pads along the first direction X, and the ground pad S46, the third signal output pad S43 and the second access pad S45 are arranged as a second column of driving pads along the first direction X. In this case, the orthographic projection of the data signal line L3 in a set of first signal lines 101 on the plane where the backplane 100 is disposed is overlapped with the orthographic projection of the first column of driving pads on the plane where the backplane 100 is disposed.

In some embodiments, in the light-emitting unit 200, the driving portion 202 is disposed on the side of the plurality of light-emitting portions 201 away from the first common electrode signal line L1. Since two columns of pads are arranged in the driving pad group S40, in order to ensure that the first signal lines 101 in a set of first signal lines 101 are compactly arranged, it needs to be ensured that the first column of driving pads where the first access pad S44 is disposed in the driving pad group S40 is closer to the first common electrode signal line L1 than the second column of driving pads is. That is, the first pad group S10, the second pad group S20 and the third pad group S30 that correspond to one light-emitting unit 200 are all disposed on the side of the first column of driving pads away from the second column of driving pads, and in the first pad group S10, the second pad group S20 and the third pad group S30 that correspond to one light-emitting unit 200, the first column of electrode pads is disposed on the side of the second column of electrode pads away from the first column of driving pads. Therefore, the first signal output pad S41 in the driving pad group S40 is disposed adjacent to the second electrode pad S12 in the first pad group S10 in the second direction Y, such that the first signal output pad S41 and the second electrode pad S12 are electrically connected directly through a sixth connection signal line Z6; and the second signal output pad S42 in the driving pad group S40 is disposed adjacent to the fourth electrode pad S22 in the second pad group S20 in the second direction Y, such that the second signal output pad S42 and the fourth electrode pad S22 are electrically connected directly through a seventh connection signal line Z7.

Since the second column of driving pads where the third signal output pad S43 is disposed in the driving pad group S40 is disposed on the side of the first column of driving pads away from the plurality of light-emitting portions 201, the distance between the third signal output pad S43 and the sixth electrode pad S32 in the third pad group S30 is relatively long. Therefore, in the embodiments of the present disclosure, a bending trace Z8 is further integrated in the backplane 000, and two ends of the bending trace Z8 are electrically connected to the third signal output pad S43 and the sixth electrode pad S32, respectively. In this way, the third signal output pad S43 is electrically connected to the sixth electrode pad S32 through the bending trace Z8. The bending trace Z8 is disposed in the same layer as various pads integrated in the backplane 100, and therefore the two ends of the bending trace Z8 are directly electrically connected to the third signal output pad S43 and the sixth electrode pad S32. It should be noted that the bending trace Z8 only needs to connect the third signal output pad S43 and the sixth electrode pad S32, the bending trace Z8 occupies a smaller space of the backplane 100, and the bending trace Z8 does not affect the area of the functional region P in the backplane 100. In this way, the area of the functional region Pin the backplane 100 can be further increased.

In the embodiments of the present disclosure, the backplane 100 is provided with a first via hole V1 for connecting the first access pad S44 and the data signal line L3. The bending trace Z8 in the backplane 100 includes a first portion Z81, a second portion Z82, and a third portion Z83. The first portion Z81 of the bending trace Z8 is arranged on the side of the first via hole V1 away from the first access pad S44 in the first direction X, and the second portion Z82 and the third portion Z83 of the bending trace Z8 are arranged on two sides of the first via hole V1 in the second direction Y. The third signal output pad S43, the second portion Z82 of the bending trace Z8, the first portion Z81 of the bending trace Z8, the third portion Z83 of the bending trace Z8, and the sixth electrode pad S32 are sequentially connected in series, such that the first via hole V1 is disposed in a region enclosed by the bending trace Z8.

In the present disclosure, the backplane 100 is further provided with a second via hole V2 for connecting the ground pad S46 and the ground terminal of the backplane 100. The bending trace Z8 in the backplane 100 further includes a fourth portion Z84. The first portion Z81 and fourth portion Z84 of the bending trace Z8 are respectively disposed on two sides of the second via hole V2 in the first direction X, and the third portion Z83 of the bending trace Z8 is disposed on the side of the second via hole V2 away from the ground pad S46 in the second direction Y. The third signal output pad S43, the fourth portion Z84 of the bending trace Z8, the second portion Z82 of the bending trace Z8, the first portion Z81 of the bending trace Z8, the third portion Z83 of the bending trace Z8 and the sixth electrode pad S32 are sequentially connected in series, such that the first via hole V1 and the second via hole V2 are both disposed in the region enclosed by the bending trace Z8. In this way, it can be ensured that the conductive structures configured to connect the driving portion 202 and the light-emitting portions 201 in the backplane 100 are distributed more compactly, and it can be ensured that the conductive structures configured to connect the light-emitting units and the signal lines are distributed more compactly. Thus, the area of the functional region P in the backplane 100 can be further increased, and the through hole K disposed in the functional region P can have a larger size.

It should be noted that, in order to ensure that the bending trace Z8 does not interfere with the distribution of the first via hole V1 and the second via hole V2, the bending trace Z8 further includes a first avoiding portion Z85 and a second avoiding portion Z86. The first avoiding portion Z85 is disposed between the third signal output pad S43 and the fourth portion Z84 of the bending trace Z8, and the first avoiding portion Z85 extends along a direction going away from the second via hole V2 while extending along the second direction Y. The second avoiding portion Z86 is disposed between the sixth electrode pad S32 and the second portion Z82 of the bending trace Z8, and the second avoiding portion Z86 extends along a direction going away from the first via hole V1 while extending along the first direction X. In this way, by providing the first avoiding portion Z85 and the second avoiding portion Z86 in the bending trace Z8, it is ensured that the bending trace Z8 can avoid the first via hole V1 and the second via hole V2, thereby effectively increasing the area of the region where the first via hole V1 and the second via hole V2 are formed (i.e., the region enclosed by the bending trace Z8), such that the reliability of the display panel 000 is high.

Two ends of the first avoiding portion Z85 are connected to an end of the third signal output pad S43 and an end of the fourth portion Z84 respectively, and the first avoiding portion Z85 extends along a fold line, such that the first avoiding portion Z85 can avoid the second via hole V2. Similarly, two ends of the second avoiding portion Z86 are connected to an end of the sixth electrode pad S32 and an end of the second portion Z82 respectively, and the second avoiding portion Z86 extends along a fold line, such that the second avoiding portion Z86 can avoid the first via hole V1.

In the embodiments of the present disclosure, for the ground pad S46, the third signal output pad S43 and the second access pad S45 that are arranged in one column in the driving pad group S40, since the second access pad S45 needs to be electrically connected to the second signal line 102 through the fifth connection signal line Z5, the second access pad S45 is disposed at a position closest to the second signal line 102 in order to ensure that the signal lines integrated in the backplane 100 are distributed compactly. That is, the second access pad S45 is closer to the second signal line 102 electrically connected to the second access pad S45 than the ground pad S46 is, and the second access pad S45 is closer to the second signal line 102 than the third signal output pad S43 is. In addition, since the ground pad S46 needs to be electrically connected to the ground terminal of the backplane 100 through the second via hole V2, and the second via hole V2 usually has a larger area, the distance between the second via hole V2 and the second signal line 102 needs to be relatively long in order to ensure that the second via hole V2 does not affect the distribution of the second signal line 102. Therefore, the ground pad S46 is disposed at a position farthest away from the second signal line 102. In this way, in the driving pad group S40, the third signal output pad S43 needs to be disposed between the ground pad S46 and the second access pad S45.

For the first access pad S44, the first signal output pad S41 and the second signal output pad S42 arranged in one column in the driving pad group S40, since the second electrode pad S12 is disposed between the fourth electrode pad S22 and the sixth electrode pad S32, the first signal output pad S41 in the driving pad group S40 is disposed between the first access pad S44 and the second signal output pad S42 in order to facilitate the connection between the driving pad group S40 and the pad group corresponding to the light-emitting portion. In addition, since the first access pad S41 needs to be electrically connected to the data signal line L3 through the first via hole V1, and the first via hole V1 usually has a larger area, the distance between the first via hole V1 and the second signal line 102 needs to be relatively long in order to ensure that the first via hole V1 does not affect the distribution of the second signal line 102. Therefore, the first access pad S44 is disposed at a position farthest away from the second signal line 102.

In this case, in the driving pad group S40, the first access pad S44 and the ground pad S46 are arranged adjacently in the second direction Y, the first signal output pad S41 and the third signal output pad S43 are arranged adjacently in the second direction Y, and the second signal output pad S42 and the second access pad 45 are arranged adjacently in the second direction Y.

For example, assuming that the first common electrode signal line L1 and the second common electrode signal line L2 in a set of first signal lines 101 both provide anode signals, when the display panel 000 needs to control a light-emitting unit 200 to emit light, a power driving signal can be applied to the power signal line electrically connected to the light-emitting unit 200 in the display panel 000, and a data signal can be applied to the data signal line L3 electrically connected to the light-emitting unit 200. In this way, after the driving portion 202 of the light-emitting unit 200 receives the power driving signal through the second access pad S45, the driving portion 202 is in a working state. After the driving portion 202 receives the data signal through the first access pad S44, the driving portion 202 generates three cathode signals corresponding to the three light-emitting portions 201 based on the data signal. The three cathode signals are transmitted to the cathode pins of the three light-emitting portions 201 through the three signal output pads, respectively. Since the anode pin of the light-emitting portion 201 always receives the anode signal, after the light-emitting portion 201 receives the anode signal and the cathode signal, the light-emitting portion 201 emits light of a corresponding intensity.

In the embodiments of the present disclosure, as shown in FIG. 4, a set of second signal lines 102 in the backplane 100 includes at least one second signal line 102. For example, a set of second signal lines 102 includes only one second signal line 102, and the second signal line 102 is a power signal line.

In order to more clearly show the structure of the second signal line 102 integrated in the backplane 100, please refer to FIG. 9, and FIG. 9 is a schematic structural diagram of a second signal line according to some embodiments of the present disclosure. The second signal line 102 includes a plurality of third bending structures 1021 and a plurality of fourth bending structures 1022. In the second signal line 102, the plurality of third bending structures 1021 and the plurality of fourth bending structures 1022 are alternately arranged one by one, and an opening of the third bending structure 1021 is oriented in an opposite direction to an opening of the fourth bending structure 1022. For example, the opening of the third bending structure 1021 faces the lower side of the second signal line 102, and the opening of the fourth bending structure 1022 faces the upper side of the second signal line 102.

For example, FIG. 10 is a schematic structural diagram of another second signal line according to some embodiments of the present disclosure. The second signal line 102 includes a plurality of third extension portions F1 and a plurality of fourth extension portions F2, and second connection portions F3 for connecting the third extension portions F1 and the fourth extension portions F2. Here, the plurality of third extension portions F1 and the plurality of fourth extension portions F2 in the second signal line 102 are alternately arranged one by one, and the extension directions of the plurality of third extension portions F1 are parallel to the extension directions of the plurality of fourth extension portions F2. For example, the extension direction of the third extension portion F1 and the extension direction of the fourth extension portion F2 are both parallel to the second direction Y. The second connection portion F3 in the second signal line 102 is disposed between the third extension portion F1 and the fourth extension portion F2, the third extension portion F1 is connected to one end of the second connection portion F3, and the fourth extension portion F2 is connected to the other end of the second connection portion F3.

The extension direction of the second connection portion F3 intersects with the extension direction of the third extension portion F1, and intersects with the extension direction of the fourth extension portion F2. In this case, the third extension portion F1 and the two second connection portions F3 connected to the two ends of the third extension portion F1 constitute one third bending structure 1021; and the fourth extension portion F2 and the two second connection portions F3 connected to the two ends of the fourth extension portion F2 constitute one fourth bending structure 1022.

In the present disclosure, the opening of the third bending structure 1021 in the second signal line 102 faces the functional portion. In a possible implementation, in the case that the functional portion is a through hole K, a part of the through hole K disposed in the functional region P extends to a region enclosed by the third bending structure 1021. Here, the region enclosed by the third bending structure 1021 refers to a region enclosed by the third bending structure 1021 and the extended line of the fourth extension portion F2 which is at the position where the third bending structure 1021 is disposed. In this way, by providing the third bending structure 1021 in the second signal line 102, and making a part of the through hole K extend to the region enclosed by the third bending structure 1021, the area of the opening of the through hole K disposed in the functional region P can be further increased.

Additionally, the opening of the fourth bending structure 1022 in the second signal line 102 faces the light-emitting unit 200. In this way, it can be ensured that the light-emitting unit 200 in the display panel 000 does not occupy too much of the functional region P, and it can be further ensured that the through hole K of a larger size can be provided in the functional region P.

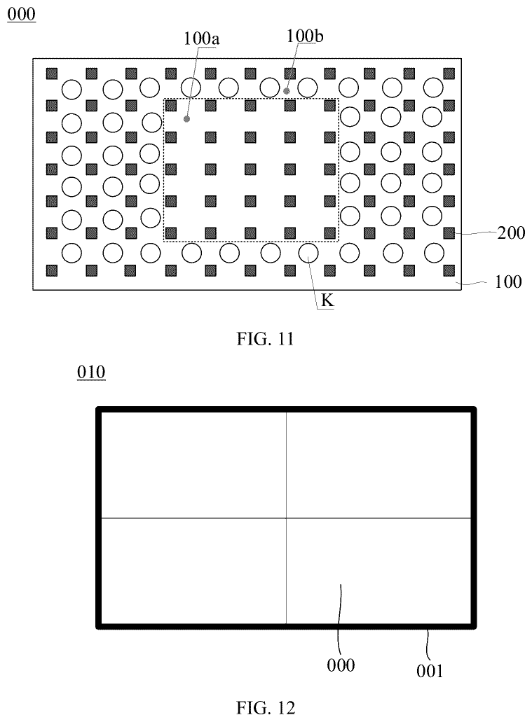

In some embodiments, referring to FIG. 11, and FIG. 11 is a top view of another display panel according to some embodiments of the present disclosure. The backplane 100 is provided with a device fixing region 100a and a sound transmission region 100b surrounding the device fixing region 100a. In the sound transmission region 100b, a through hole K is provided in the region enclosed by adjacent first signal lines 101 and adjacent second signal lines 102; and in the device fixing region 100a, no through hole K is provided in the region enclosed by adjacent first signal lines 101 and adjacent second signal lines 102. That is, the plurality of through holes K in the backplane 100 are all distributed in the sound transmission region 100b and are all distributed outside the device-fixing region 100a.

In the embodiments of the present disclosure, the display panel 000 further includes a driving control module fixed on the back surface of the display panel. The driving control module is disposed in the device fixing region 100a of the display panel 000, and the driving control module is configured to send a driving signal to the first signal line 101 and the second signal line 102. The driving control module in the display panel 000 generally includes a plurality of elements. For example, the driving control module in the display panel 000 includes a plug connector, such that the signal access circuit board is electrically plugged in the plug connector through a line to implement the electrical connection between the signal access circuit board and the display panel. In the present disclosure, the elements in the driving control module are fixed on the side of the backplane 100 away from the plurality of light-emitting units 200 in the display panel 000 in a welding manner. When the driving control module is disposed in the device fixing region 100a, since no through hole K is provided in the device fixing region 100a, it can be ensured that the elements can be stably fixed in the device fixing region 100a. In this case, the display panel 000 not only can transmit the sound from the stereo through the plurality of through holes K provided in the sound transmission region 100b, but also can stably fix the driving control module through the device fixing region 100a.

In some embodiments, the backplane 100 in the display panel 000 is a printed circuit board. In this way, even if a large number of through holes K are formed in the backplane 100, the overall strength of the backplane 100 can be ensured to be relatively high. Certainly, in another possible implementation, the backplane 000 includes a substrate, and the first signal line 101 and the second signal line 102 are disposed on a side of the substrate. The substrate may be a glass substrate.

In summary, the display panel provided in the embodiments of the present disclosure includes a backplane and a plurality of light-emitting units. In the backplane of the display panel, a through hole penetrating through the backplane is provided in a region enclosed by at least part of the adjacent first signal lines and at least part of the adjacent second signal lines. In this way, through holes are distributed in the backplane of the display panel, and these through holes can serve as sound transmission holes. Even if the stereo is arranged on the back surface of the display panel, the sound from the stereo can be transmitted out from the sound transmission holes in the display panel, thereby ensuring that the display panel does not shield the sound from the stereo. Therefore, the display panel can be used as an acoustically transparent display panel, and the sound from the stereo arranged on the back surface of the display panel can be directly transmitted out from the display surface of the display panel. Thus, the display panel has both a display function and a sound transmission function, which effectively enriches the functions of the display panel, such that the display panel has better effects in use.

The embodiments of the present disclosure further provide a display module. Referring to FIG. 12 and FIG. 13, FIG. 12 is a top view of a display module according to some embodiments of the present disclosure, and FIG. 13 is an exploded view of the display module shown in FIG. 12. The display module 010 includes a box 001, a display panel 000 disposed on a side of the box 001, and a stereo 002 disposed between the box 001 and the display panel 000. A sound emitting surface of the stereo 002 faces the display panel 000. Here, each display panel in the display module 010 is the display panel in the foregoing embodiments, and the stereo 002 is disposed on the side, away from the plurality of light-emitting units 200, of the backplane 100 in the display panel 000.

In the present disclosure, the backplane 100 in the display panel 000 in the foregoing embodiments is provided with a through hole K penetrating through the entire backplane 100. Therefore, by disposing the stereo 002 on the side of the backplane 100 away from the plurality of light-emitting units 200 and arranging the sound emitting surface of the stereo 002 to face the display panel 000, the sound from the stereo 002 can be transmitted out through the through hole K, such that the sound from the stereo 002 in the display module 010 can be transmitted out from the display side of the display module 010.

In some embodiments, the display module 010 further includes a signal access circuit board 003 disposed between the box 001 and the plurality of display panels 000. The signal access circuit board 003 is electrically connected to the driving control module in the display panel 000. Here, the signal access circuit board may also be electrically connected to a control device, such that the control device can send to-be-displayed signals to the display panels through the signal access circuit board.

In the present disclosure, the surface where the signal access circuit board 003 is disposed intersects with the surface where the display panel 000 is disposed. For example, the surface where the signal access circuit board 003 is disposed is perpendicular to the surface where the display panel 000 is disposed. In this way, it can be ensured that the signal access circuit board 003 does not shield the sound from the stereo 002 on the premise that the signal access circuit board 003 is normally connected to the display panel 000.

For example, a plurality of display panels 000 are provided in the display module 010, and the plurality of display panels 000 are spliced with each other and arranged in an array. At least one signal access circuit board 003 is provided in the display module 010. The box 001 in the display module 010 has an accommodation cavity O, the plurality of display panels 000 spliced with each other in the display module 010 are connected to the box 001 at the opening of the accommodation cavity O, and the stereo 002 and the at least one signal access circuit board 003 in the display module 010 are disposed in the accommodation cavity O. In a direction parallel to the sound emitting surface of the stereo 002, the signal access circuit board 003 is disposed on at least one side of the stereo 002 in the accommodation cavity O. For example, in the case that a plurality of signal access circuit boards 003 are provided, the plurality of signal access circuit boards 003 are divided into two groups, and each group of signal access circuit boards 003 includes at least one signal access circuit board 003. Here, in the case that a group of signal access circuit boards 003 includes multiple signal access circuit boards 003, these signal access circuit boards 003 are laminated. In addition, in the accommodation cavity O, the two groups of signal access circuit boards 003 are respectively disposed on two opposite inner side surfaces of the accommodation cavity O, and the stereo 002 is disposed between the two groups of signal access circuit boards 003. In this way, the sound from the stereo 002 is not shielded by the signal access circuit board 003, and the stereo 002 can emit sound directly towards the plurality of display panels 000, such that the sound can be transmitted out through the through holes provided in the display panels 000.

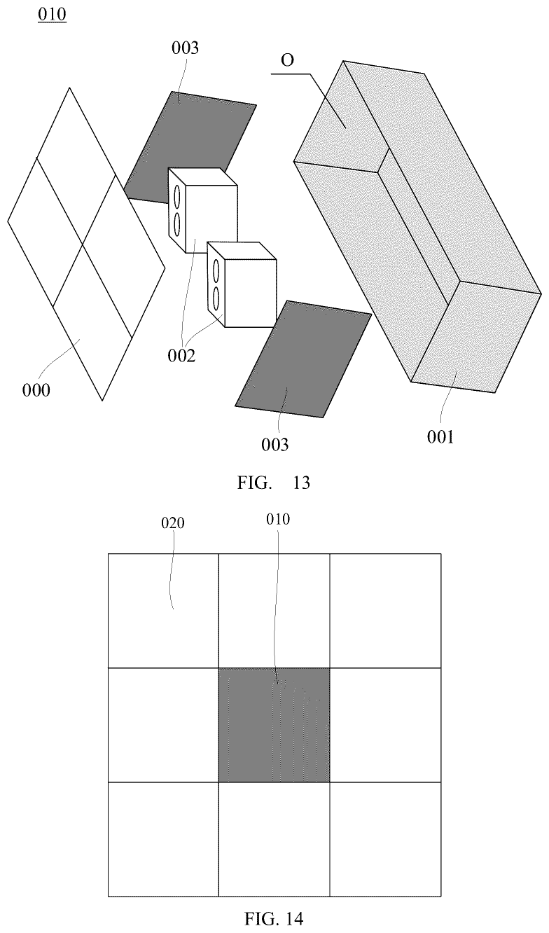

The embodiments of the present disclosure further provide a display system. Referring to FIG. 14, FIG. 14 is a schematic structural diagram of a display system according to some embodiments of the present disclosure. The display system includes a plurality of spliced first display modules 010, and each of the first display modules 010 is the display module 010 in the foregoing embodiments, for example, the display module shown in FIG. 13.

In some embodiments, the display system further includes a plurality of spliced second display modules 020. In the display system, the second display module 020 is also spliced with the first display module 010. Therefore, in the display system, the plurality of first display modules 010 and the plurality of second display modules 020 are spliced to form a large display screen, and the large display screen may be a cinema screen, an advertisement screen, or the like.

In the embodiments of the present disclosure, the second display module 020 includes a plurality of passive display panels spliced with each other.

It should be noted that each light-emitting unit in the plurality of display panels in the first display module 010 includes a driving portion and a plurality of light-emitting portions electrically connected to the driving portion. Therefore, each display panel in the first display module 010 is an active display panel. For the passive display panel, each light-emitting unit in the display panel includes a plurality of light-emitting portions, but does not include a driving portion. Therefore, a large number of elements need to be integrated on the back surface of the passive display panel, and the light-emitting states of the light-emitting units in the passive display panel are controlled through the elements. For example, the elements integrated on the back surface of the passive display panel include a plurality of row drive elements and a plurality of column drive elements, each row drive element is correspondingly connected to at least one row of light-emitting units, and each column drive element is correspondingly connected to at least one column of light-emitting units. When a light-emitting unit needs to emit light, the row drive element connected to the row of light-emitting units where the light-emitting unit is disposed and the column drive element connected to the column of light-emitting units where the light-emitting unit is disposed are called to work simultaneously, and the corresponding light-emitting unit is controlled to emit light under the cooperation of the row drive element and the column drive element. It should be noted that in other possible implementations, one row drive element and one column drive element are integrated as a whole, and this element is electrically connected to the corresponding at least one row of light-emitting units and the corresponding at least one column of light-emitting units simultaneously.

Additionally, the large number of elements need to be uniformly arranged on the back surface of the passive display panel. Therefore, the through holes for transmitting sound cannot be arranged in the passive display panel any more, and thus no stereo is arranged in the second display module 020.

It should also be noted that, the manufacturing cost of the passive display panel is much lower than that of the active display panel, and the display system can emit sound through the stereo disposed in the first display module 010. Therefore, in the case that the display system includes a plurality of first display modules 010 and a plurality of second display modules 020, it can not only be ensured that the sound can be transmitted out from the display side of the display system, but also can be ensured that the overall manufacturing cost of the display system is low.

In the embodiments of the present disclosure, the display system further includes a control device electrically connected to the plurality of first display modules and the plurality of second display modules. The control device is configured to: divide, based on position information of each of the first display modules and position information of each of the second display modules, an original video source to be displayed into a first video source corresponding to the first display module and a second video source corresponding to the second display module, and send the corresponding first video source to each of the first display modules, and send the corresponding second video source to each of the second display modules.

In this case, because the display principle of the first display module is different from the display principle of the second display module, the original video source to be displayed needs to be divided through the control device into a plurality of first video sources and a plurality of second video sources, such that the first display modules display pictures according to the first video sources, and the second display modules display pictures according to the second video sources, thereby ensuring that the entire display system can display pictures.

It should be noted that in the drawings, the dimensions of layers and regions may be exaggerated for clarity of illustration. It is to be further understood that when an element or layer is referred to as being “on” another element or layer, it may be directly on other elements, or an intermediate layer may be present. Additionally, it is to be understood that when an element or layer is referred to as being “under” another element or layer, it may be directly under other elements, or more than one intermediate layer or element may be present. Additionally, it is to be understood that when a layer or element is referred to as being “between” two layers or two elements, it may be the unique layer between the two layers or two elements, or more than one intermediate layer or element may be present. Similar reference numerals indicate similar elements throughout.

In the present disclosure, the terms “first” and “second” are used for descriptive purposes only and are not to be construed as indicating or implying relative importance. The term “a plurality of” refers to two or more, unless expressly specified otherwise.

Described above are merely optional embodiments of the present disclosure, and are not intended to limit the present disclosure. Within the spirit and principles of the disclosure, any modifications, equivalent substitutions, improvements, and the like are within the protection scope of the present disclosure.

1. A display panel, comprising:
a backplane; and
a plurality of light-emitting units arranged in an array on a side of the backplane, wherein the light-emitting unit comprises a driving portion and a plurality of light-emitting portions that are fixed on the backplane;
wherein the backplane is integrated with a plurality of sets of first signal lines and a plurality of sets of second signal lines, wherein a set of the first signal lines is electrically connected to each of the light-emitting units arranged along a first direction, and a set of the second signal lines is electrically connected to each of the light-emitting units arranged along a second direction, the first direction being different from the second direction;
wherein a functional portion is provided in a region enclosed by at least part of adjacent first signal lines and at least at least part of adjacent second signal lines, and the functional portion is a through hole penetrating through the backplane.

2. The display panel according to claim 1, wherein a set of the first signal lines comprises a plurality of first signal lines, and at least one first signal line of the set of the first signal lines comprises a plurality of first bending structures and a plurality of second bending structures, wherein the plurality of first bending structures and the plurality of second bending structures are alternately arranged one by one, and an opening of the first bending structure is oriented in an opposite direction to an opening of the second bending structure;
wherein the opening of the first bending structure faces the functional portion.

3. The display panel according to claim 2, wherein
at least one of the plurality of light-emitting portions of the light-emitting unit is electrically connected to the first signal line;
the opening of the second bending structure faces the light-emitting unit.

4. The display panel according to claim 3, wherein the plurality of light-emitting portions comprise a first light-emitting portion, and the backplane is further integrated with a first pad group electrically connected to the first light-emitting portion and a driving pad group electrically connected to the driving portion; wherein
the first pad group comprises a first electrode pad and a second electrode pad, wherein the first electrode pad is electrically connected to the second bending structure; and
the driving pad group comprises a first signal output pad corresponding to the first pad group, wherein the first signal output pad is electrically connected to the second electrode pad in the first pad group.

5. The display panel according to claim 4, wherein the plurality of light-emitting portions further comprise a second light-emitting portion and a third light-emitting portion, and the backplane is further integrated with a second pad group electrically connected to the second light-emitting portion and a third pad group electrically connected to the third light-emitting portion; wherein
the second pad group comprises a third electrode pad and a fourth electrode pad, and the driving pad group further comprises a second signal output pad corresponding to the second pad group, wherein the second signal output pad is electrically connected to the fourth electrode pad in the second pad group;
the third pad group comprises a fifth electrode pad and a sixth electrode pad, and the driving pad group further comprises a third signal output pad corresponding to the third pad group, wherein the third signal output pad is electrically connected to the sixth electrode pad in the third pad group.

6. The display panel according to claim 5, wherein
the first electrode pad and the third electrode pad are a same pad; or
the first electrode pad and the fifth electrode pad are a same pad; or
the third electrode pad and the fifth electrode pad are a same pad; or
the first electrode pad, the third electrode pad, and the fifth electrode pad are a same pad.

7. The display panel according to claim 5, wherein a set of the first signal lines comprises: a data signal line and a first common electrode signal line; the first common electrode signal line comprising the first bending structure and the second bending structure; and the driving pad group further comprises a first access pad electrically connected to the data signal line; wherein
the first access pad and at least two signal output pads are arranged in one column, wherein the at least two signal output pads are at least two of the first signal output pad, the second signal output pad, and the third signal output pad.

8. The display panel according to claim 7, wherein
the first access pad and the at least two signal output pads are arranged along the first direction;
the second electrode pad, the fourth electrode pad, and the sixth electrode pad are arranged along the first direction.

9. The display panel according to claim 7, wherein an orthographic projection of the data signal on a plane where the backplane is disposed is overlapped with orthographic projections of the first access pad and the signal output pads arranged in one column along the first direction on the plane where the backplane is disposed.

10. The display panel according to claim 7, wherein the backplane is further integrated with a bending trace, and two ends of the bending trace are electrically connected to the third signal output pad and the sixth electrode pad, respectively;
the backplane is provided with a first via hole for connecting the first access pad and the data signal line, wherein a first portion of the bending trace is disposed on a side of the first via hole away from the first access pad in the first direction, and a second portion and a third portion of the bending trace are respectively disposed on two sides of the first via hole in the second direction; wherein the third signal output pad, the second portion of the bending trace, the first portion of the bending trace, the third portion of the bending trace, and the sixth electrode pad are sequentially connected in series.

11. The display panel according to claim 10, wherein
the first access pad, the first signal output pad and the second signal output pad are arranged as a first column of driving pads along the first direction;
the third signal output pad is disposed on a side of the first column of driving pads away from the plurality of light-emitting portions;
the driving pad group further comprises a ground pad, and the backplane is further provided with a second via hole for connecting the ground pad and a ground terminal of the backplane, wherein the first portion of the bending trace and a fourth portion of the bending trace are respectively disposed on two sides of the second via hole in the first direction, and the third portion of the bending trace is disposed on a side of the second via hole away from the ground pad in the second direction; wherein the third signal output pad, the fourth portion of the bending trace, the second portion of the bending trace, the first portion of the bending trace, the third portion of the bending trace, and the sixth electrode pad are sequentially connected in series.

12. The display panel according to claim 7, wherein the driving pad group further comprises a second access pad and a ground pad, the second access pad being electrically connected to the second signal line, and the ground pad being electrically connected to a ground terminal of the backplane;
in one driving pad group, the first access pad, the first signal output pad and the second signal output pad are arranged as a first column of driving pads along the first direction, and the ground pad, the third signal output pad and the second access pad are arranged as a second column of driving pads along the first direction;
the first pad group, the second pad group and the third pad group corresponding to one of the light-emitting units are all disposed on a side of the first column of driving pads away from the second column of driving pads.

13. The display panel according to claim 12, wherein in the first pad group, the second pad group and the third pad group corresponding to one of the light-emitting units, the first electrode pad, the third electrode pad and the fifth electrode pad are arranged as a first column of electrode pads along the first direction, the second electrode pad, the fourth electrode pad and the sixth electrode pad are arranged as a second column of electrode pads along the first direction, wherein the first column of electrode pads is disposed on a side of the second column of electrode pads away from the first column of driving pads.

14. The display panel according to claim 12, wherein the first access pad and the ground pad are arranged adjacently in the second direction, the third signal output pad is disposed between the ground pad and the second access pad, and the second access pad is closer to the second signal line electrically connected to the second access pad than the ground pad is.

15. The display panel according to claim 12, wherein the first electrode pad, the third electrode pad and the fifth electrode pad are arranged in one column along the first direction, and the first electrode pad is disposed between the third electrode pad and the fifth electrode pad;
a set of the first signal lines further comprises a second common electrode signal line, the second common electrode signal line comprising the first bending structure and the second bending structure;
wherein the first electrode pad is electrically connected to the second bending structure in the first common electrode signal line, and the third electrode pad and the fifth electrode pad are electrically connected to the second common electrode signal line;
optionally, wherein the second common electrode signal line is closer to the plurality of light-emitting portions of the light-emitting unit than the first common electrode signal line is; and a bending degree of the first bending structure in the second common electrode signal line is less than a bending degree of the first bending structure in the first common electrode signal line; and a bending degree of the second bending structure in the second common electrode signal line is less than a bending degree of the second bending structure in the first common electrode signal line.

16. (canceled)

17. The display panel according to claim 5, wherein the first light-emitting portion is a red light-emitting portion for emitting red light, the second light-emitting portion is one of a green light-emitting portion for emitting green light and a blue light-emitting portion for emitting blue light, and the third light-emitting portion is the other one of the green light-emitting portion and the blue light-emitting portion.

18. The display panel according to claim 2; wherein the at least one first signal line comprises: a plurality of first extension portions, a plurality of second extension portions, and a first connection portion for connecting the first extension portion and the second extension portion; wherein
the plurality of first extension portions and the plurality of second extension portions are alternately arranged one by one, an extension direction of the first extension portion is parallel to an extension direction of the second extension portion, the first connection portion is disposed between the first extension portion and the second extension portion that are adjacent to each other, the first extension portion is connected to one end of the first connection portion, and the second extension portion is connected to other end of the first connection portion; and
the first extension portion and two first connection portions connected to two ends of the first extension portion constitute one first bending structure, and the second extension portion and two first connection portions connected to two ends of the second extension portion constitute one second bending structure; and/or
wherein a set of the second signal lines comprises at least one second signal line, and the at least one second signal line comprises a plurality of third bending structures and a plurality of fourth bending structures; wherein the plurality of third bending structures and the plurality of fourth bending structures are alternately arranged one by one, and an opening of the third bending structure is oriented in an opposite direction to an opening of the fourth bending structure;
wherein the opening of the third bending structure faces the functional portion, and the opening of the fourth bending structure faces the light-emitting unit.

19.-20. (canceled)

21. The display panel according to claim 1, wherein the backplane is provided with a device fixing region and a sound transmission region surrounding the device fixing region; wherein
in the sound transmission region, the through hole is provided in a region enclosed by adjacent first signal lines and adjacent second signal lines; and in the device fixing region, no through hole is provided in a region enclosed by adjacent first signal lines and adjacent second signal lines;
optionally, the display panel further comprises a driving control module fixed on a back surface of the display panel, wherein the driving control module is disposed in the device fixing region, and the driving control module is configured to send a driving signal to the first signal line and the second signal line.

22.-23. (canceled)

24. A display module, comprising: a box, a display panel disposed on a side of the box, a stereo disposed between the box and the display panel, and a signal access circuit board disposed between the box and the display panel, wherein a sound emitting surface of the stereo faces the display panel, the signal access circuit board is configured to be electrically connected to a driving control module in the display panel, and a surface where the signal access circuit board is disposed intersects with a surface where the display panel is disposed;
wherein the display panel comprises: a backplane; and a plurality of light-emitting units arranged in an array on a side of the backplane, wherein the light-emitting unit comprises a driving portion and a plurality of light-emitting portions that are fixed on the backplane; wherein the backplane is integrated with a plurality of sets of first signal lines and a plurality of sets of second signal lines, wherein a set of the first signal lines is electrically connected to each of the light-emitting units arranged along a first direction, and a set of the second signal lines is electrically connected to each of the light-emitting units arranged along a second direction, the first direction being different from the second direction; wherein a functional portion is provided in a region enclosed by at least part of adjacent first signal lines and at least at least part of adjacent second signal lines, and the functional portion is a through hole penetrating through the backplane;
optionally, a plurality of display panels are provided, and the plurality of display panels are arranged in an array; the box has an accommodation cavity, at least one signal access circuit board is provided, and the at least one signal access circuit board and the stereo are disposed in the accommodation cavity; wherein in a direction parallel to the sound emitting surface of the stereo, the signal access circuit board is disposed on at least one side of the stereo in the accommodation cavity.

25.-26. (canceled)

27. A display system, comprising: a plurality of first display modules spliced with each other, wherein the first display module is the display module according to claim 24;
the display system further comprising: a plurality of second display modules spliced with each other, the second display module being spliced with the first display module;
wherein the second display module comprises a plurality of passive display panels spliced with each other.

28. (canceled)
